(19) United States
(12) Patent Application Publication
(10) Pub. No.: US 2009/0261469 A1
(43) Pub. Date: Oct. 22, 2009

(54) SEMICONDUCTOR PACKAGE AND METHOD FOR MANUFACTURING THE SAME

(76) Inventor: Qwan Ho CHUNG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/345,782

(22) Filed: Dec. 30, 2008

(30) Foreign Application Priority Data
Apr. 21, 2008 (KR) 10-2008-0036626
Dec. 24, 2008 (KR) 10-2008-0132852

(51) Int. Cl. H01L 23/49; H01L 21/02

(52) U.S. Cl. 257/690; 438/118; 257/E23.024; 257/E21.002

(57) ABSTRACT

Manufacturing a semiconductor package includes preparing a semiconductor chip having a top surface with bumps electrically connected to bonding pads, a bottom surface opposite to the top surface and side surfaces joining the top surface to the bottom surface. The bottom surface of the semiconductor chip is attached to a base substrate. A heat pressure process is performed to form a wiring support member on the base substrate to cover the top surface and the side surfaces of the semiconductor chip while exposing each of the bumps. Wirings are formed to be electrically connected to the bumps on the wiring support member. The base substrate is removed from the semiconductor chip and the wiring support member.

### CROSS-REFERENCE TO RELATED APPLICATIONS

The present application claims priority to Korean patent application number 10-2008-0036626 filed on Apr. 21, 2008, Korean patent application number 10-2008-0132852 filed on Dec. 24, 2008, which are incorporated herein by reference in their entireties.

### BACKGROUND OF THE INVENTION

The present invention relates generally to semiconductor devices, and more particularly to a semiconductor package and a method for manufacturing the same.

Recent developments in semiconductor chip technology include semiconductor chips capable of both storing an enormous amount of data and processing the enormous amount of data within a short period of time, and a semiconductor package containing the semiconductor chip. In order to facilitate the advancement of these technologies, various technologies are being developed to reduce the thickness of a semiconductor package and to improve upon the operation speed of the semiconductor package.

### SUMMARY OF THE INVENTION

Embodiments of the present invention include a semiconductor package with a reduced thickness and that operates at a high velocity when compared to conventional semiconductor packages.

Additionally, embodiments of the present invention include a method for manufacturing the semiconductor package.

The semiconductor package according to one aspect of the present invention includes a semiconductor chip having a top surface with bumps connected to respective bonding pads, a bottom surface opposite to the top surface and side surfaces joining the top surface to the bottom surface; a wiring support member covering the top surface and the side surfaces of the semiconductor chip while exposing each of the bumps by a heat pressure process; and a wiring disposed on the wiring support member to be electrically connected to each of the exposed bumps.

The wiring support member of the semiconductor package may include a thermo-setting resin.

The semiconductor package may further include an adhesive layer attached on the bottom surface of the semiconductor substrate.

The semiconductor package may further includes a heat sink plate disposed on the adhesive layer.

The wiring support member of the semiconductor package may comprise a molding material containing an epoxy resin.

A method for manufacturing a semiconductor package according to another aspect of the present invention includes steps of preparing a semiconductor chip having a top surface with bumps electrically connected to bonding pads, a bottom surface opposite to the top surface and side surfaces joining the top surface to the bottom surface; attaching the bottom surface on the base substrate; forming the wiring support member on the base substrate to cover the top surface and the side surfaces of the semiconductor chip while exposing each of the bumps by a heat pressure process; forming wirings electrically connected to each of the bumps on the wiring support member; and removing the base substrate from the semiconductor chip and the wiring support member.

The step of attaching the bottom surface on the base substrate may include interposing an adhesive member between the base substrate and the semiconductor chip.

The step of forming the wiring support member on the base substrate may include steps of: disposing a preliminary wiring support member containing thermo-setting material on the top surface of the semiconductor chip; and causing the preliminary wiring support member to cover the top surface and the side surfaces of the semiconductor chip and the bumps to be exposed from the preliminary wiring support member by a heat pressure process.

The step of disposing the preliminary wiring support member on the top surface of the semiconductor chip may include forming a metal layer on the preliminary wiring support member.

The step of forming the wirings may include steps of forming a photo-resist pattern on the top surface of the metal layer; and etching the metal layer using the photo-resist pattern as a pattern mask.

The step of forming the wirings may include steps of disposing a metal layer electrically connected to each of the bumps on the wiring support member; forming a photo-resist pattern on the top surface of the metal layer; and etching the metal layer using the photo-resist pattern as a pattern mask.

The wirings may also be formed via a plating process when forming the wirings.

The step of forming the wiring support member on the base substrate may include steps of: disposing a preliminary wiring support member containing thermo-setting material on the top surface of the semiconductor chip; and covering the top surface and the side surfaces of the semiconductor chip while exposing the bumps from the preliminary wiring support member by melting the preliminary wiring support member.

A method for manufacturing a semiconductor package according to another aspect of the present invention includes steps of preparing a semiconductor chip having a top surface with bumps electrically connected to bonding pads, a bottom surface opposite to the top surface, and side surfaces joining the top surface to the bottom surface; attaching the bottom surface on the base substrate; disposing the base substrate with the semiconductor chip being attached thereon within a mold; covering the top surface and the side surfaces while exposing the bonding pads by providing the molding material within the mold; forming the wirings electrically connected to each of the bumps on the wiring support member; and removing the base substrate from the semiconductor chip and the wiring support member.

The step of attaching the bottom surface on the base substrate may further include interposing an adhesive member between the base substrate and the semiconductor chip.

The method may further include steps of forming a metal layer on the wiring support member; forming a photo-resist pattern on a top surface of the metal layer; and etching the metal layer using the photo-resist pattern as a pattern mask, after forming the wiring support member.

The wirings may also be formed by a plating process in when forming the wirings.

### BRIEF DESCRIPTION OF THE DRAWINGS

FIG. 1 is a top view showing a semiconductor package according to an embodiment of the present invention.

FIG. 2 is a cross-sectional view taken along the line I-I′ of FIG. 1.

FIGS. 3 to 11 are top views and cross-sectional views shown for illustrating a method for manufacturing the semiconductor package according to an embodiment of the present invention.

FIGS. 12 to 16 are cross-sectional views shown for illustrating a method for manufacturing a semiconductor package according to another embodiment of the present invention.

FIG. 17 is a cross-sectional view shown for illustrating a semiconductor package according to another embodiment of the is present invention.

### DESCRIPTION OF SPECIFIC EMBODIMENTS

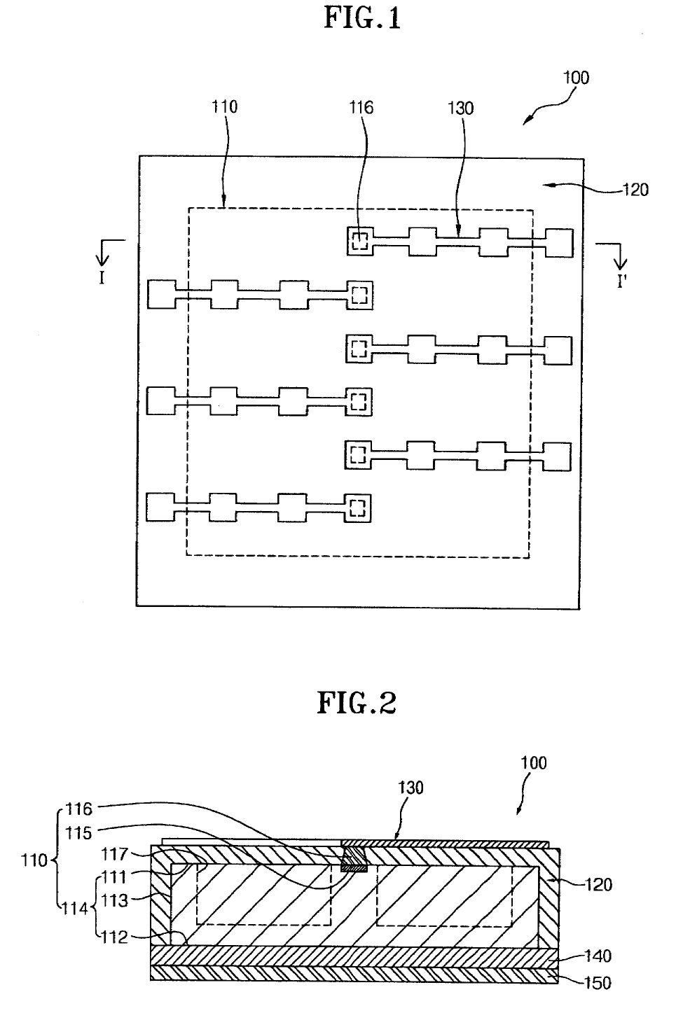

FIG. 1 is a top view showing a semiconductor package according to an embodiment of the present invention. FIG. 2 is a cross-sectional view taken along the line I-I′ of FIG. 1.

Referring to FIG. 1 and FIG. 2, the semiconductor package 100 includes a semiconductor chip 110, a wiring support member 120 and wirings 130.

The semiconductor chip 110 includes a semiconductor chip body 114, bonding pads 115, bumps 116 and circuit units 117.

In one embodiment of the present invention, the semiconductor chip body 114 has, for example, a rectangular shape. However, it should be appreciated that the semiconductor chip body is not limited only to having a rectangular shape. The semiconductor chip body 114 includes a top surface 111, a bottom surface 112 and side surfaces 113. The top surface 111 and the bottom surface 112 of the semiconductor chip body 114 are opposite to each other, and each of the side surfaces 113 joins the top and bottom surfaces 111, 112.

The circuit units 117 are disposed within the semiconductor chip body 114 and include a data storing unit (not shown) for storing data and/or a data processing unit (not shown) for processing data.

The bonding pads 115 are disposed on, for example, the top surface 111 of the semiconductor chip body 114. In the embodiment of the present invention shown in FIG. 2, the bonding pads 115 are disposed on a center portion of the top surface of the semiconductor chip body 114 (although the position of the bonding pads is not limited as such), and each of the bonding pads 115 is electrically connected to each of the circuit units 117. Alternatively, the bonding pads 115 can be disposed along the edge of the top surface of the semiconductor chip body 114.

A corresponding bump 116 is electrically connected to each of the bonding pads 115. In one embodiment of the present invention, each of the bumps 116 protrudes from the corresponding bonding pad 115 by a prescribed height. Gold, gold alloy, aluminum, and aluminum alloy are examples of metal that can be used as the material for each of the bumps 116.

The wiring support member 120 covers the top surface 111 and side surfaces 113 of the semiconductor chip body 114, and the wiring support member 120 leaves exposed each bump 116 formed on the top surface 111 of the semiconductor chip body 114.

In the embodiment of the present invention shown in FIG. 2, the top surface of the wiring support member 120 and the top surface of each bump 116 can be substantially disposed on the same surface. That is, in the embodiment of the present invention shown in FIG. 2, for example, the top surface of the wiring support member 120 and the top surface of each bump 116 are substantially co-planar. In an alternative embodiment, the bumps 116 are disposed such that the top surface of each bump 116 is positioned below the top surface of the wiring support member 120. In another embodiment, each bump 116 can be disposed such that the top surface of each bump 116 is positioned above the top surface of the wiring support member 120.

In one embodiment of the present invention, a thermo-setting resin having characteristics allowing it to be hardened by applying heat and then not softened even when heat is applied again, is an example of material suitable for use as the wiring support member 120. Thus, the wiring support member includes a material that is moldable prior to being hardened, and which is not softened by heat once the material is hardened. In an alternative embodiment, the wiring support member 120 may be formed using a molding resin such as, for example, an epoxy resin.

The wiring support member 120 containing the thermo-setting resin can be formed such that each bump 116 (which are disposed on the top surface 111 of the semiconductor chip body 114) is exposed by disposing a preliminary wiring support member (described in more detail later) having a plate shape and containing the thermo-setting resin on the top surface 111 of the semiconductor chip body 114 and applying heat and pressure to the preliminary wiring support member. Alternatively, the wiring support member 120 containing the thermo-setting resin can be formed such that each bump 116 (which are disposed on the top surface 111 of the semiconductor chip body 114) is exposed by disposing the preliminary wiring support member (shown in more detail later) having a plate shape and containing the thermo-setting resin on the top surface 111 of the semiconductor chip body 114 and melting the preliminary wiring support member.

The wirings 130 are disposed on the top surface of the wiring support member 120. The wirings 130 can be of a line shape when viewing on a plane. In the embodiment of the present invention shown in FIG. 1, a first end of each wiring 130 is electrically connected to each bump 116 exposed by the wiring support member 120, and a second end opposite to the first end of each wiring 130 is disposed on an edge of the upper surface of the wiring support member 120.

In embodiments of the present invention, methods suitable for forming the wirings 130 include patterning the metal film via a photolithography process or performing a plating process.

Meanwhile, the semiconductor package 100 according to an embodiment of the present invention may also include an adhesive layer 140. The adhesive layer 140 is disposed on, for example, the bottom layer 112 of the semiconductor chip body 114. In an embodiment of the present invention, examples of the adhesive layer 140 include a both-surface adhesion tape or an adhesive.

Meanwhile, the semiconductor package 110 according to an embodiment of the present invention can also include a heat sink plate 150. The heat sink plate 150 can be disposed on the bottom surface 112 of the semiconductor chip body 114 or on the adhesive layer 140. Examples of the heat sink plate 150 include a metal having superior heat conductivity such as, for example, copper. The heat sink plate 150 rapidly dissipates the heat generated by the semiconductor chip 110 in order to improve the performance of the semiconductor chip 110.

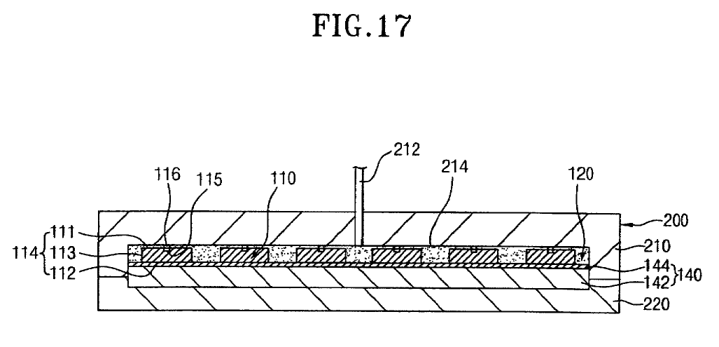

Although the wiring support member 120 containing the thermo-setting material is disposed on the top surface 111 of the semiconductor chip body 114 using a heat pressure method according to one embodiment of the present invention, the wiring support member 120 may also be formed by molding a material such as epoxy resin using a mold such that the bumps 116 are exposed. This method is described in more detail later with reference to FIG. 17.

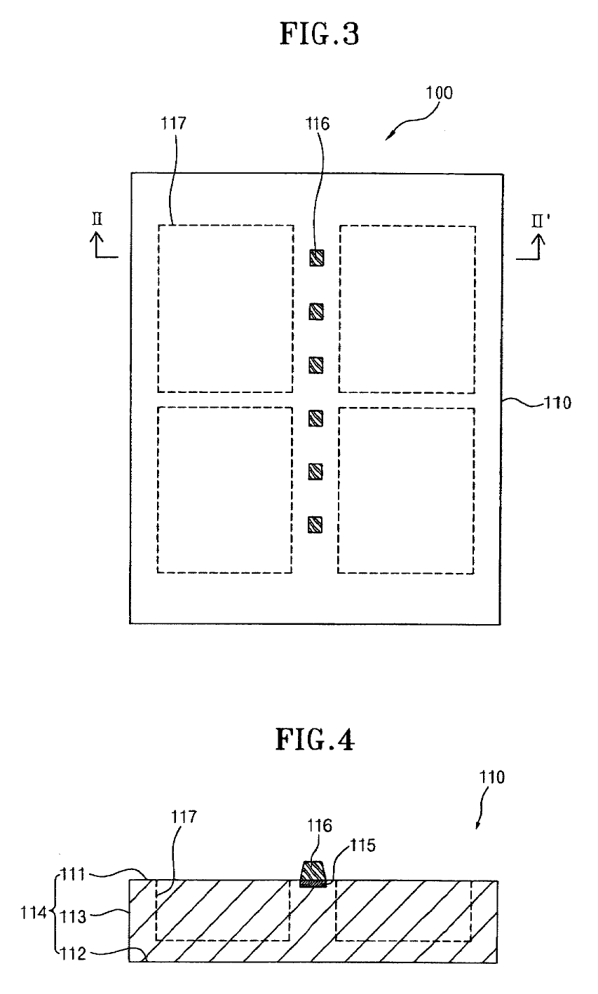

FIGS. 3 to 12 are top views and cross sectional views shown for illustrating a method for manufacturing the semiconductor package according to an embodiment of the present invention.

FIG. 3 is a top view shown for illustrating the semiconductor chip produced in accordance with the method for manufacturing the semiconductor package. FIG. 4 is a cross-sectional view taken along the line II-II′ of FIG. 3.

Referring to FIG. 3 and FIG. 4, the semiconductor chip 110 is first produced in order to produce the semiconductor package.

The semiconductor chip 110 has a semiconductor chip body 114, and bumps 116 are formed on the semiconductor chip body 116. The semiconductor chip body 114 and the bumps 116 are produced using a semiconductor production process.

The semiconductor chip body 114 is formed to have, for example, a rectangular form (although the shape of the semiconductor chip is not limited as such) and has a top surface 111, a bottom surface 112 opposite to the top surface 111 and side surfaces 113 joining the top and bottom surfaces 111, 112.

Circuit units 117 and bonding pads 115 are formed in the semiconductor chip body 114.

The circuit units 117 formed within the semiconductor chip body include a data storing unit (not shown) for storing data and a data process unit (not shown) for processing data. In one embodiment of the present invention, the bonding pads 115 are formed in a center portion of the top surface 111 of the semiconductor chip body 114, and each of the bonding pads 115 are electrically connected to the circuit units 117. In an alternative embodiment of the present invention, the bonding pads may be formed along the edge of the top surface of the semiconductor chip body 114.

Each bump 116 is formed on and is electrically connected to a respective bonding pad 115. Each of the bumps 116 (which are electrically connected to the respective bonding pads 115) protrudes from the top surface 1l of the semiconductor chip body 114 by a prescribed height.

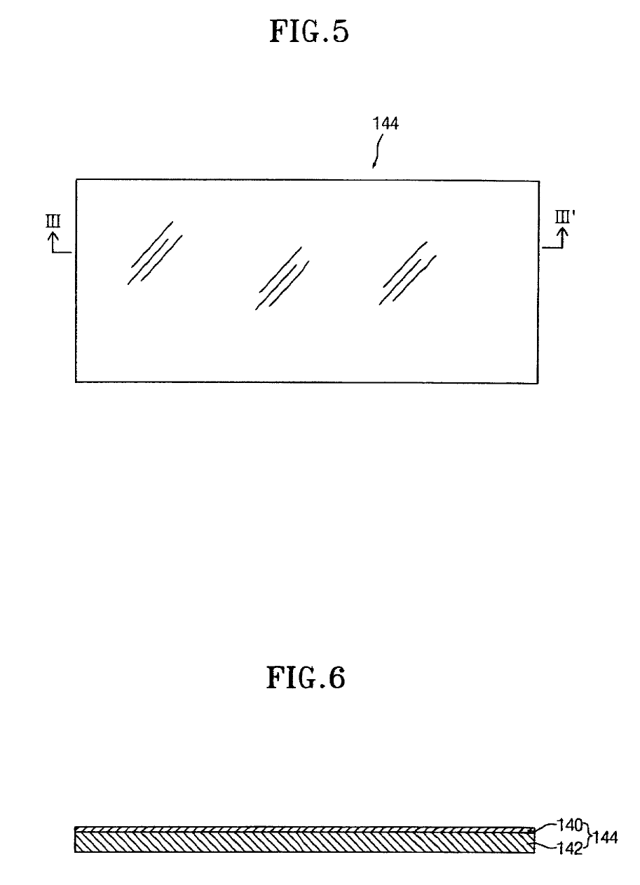

FIG. 5 is a top view shown for illustrating a base substrate on which the semiconductor chip is disposed according to an embodiment of the present invention. FIG. 6 is a cross-sectional view taken along the line III-III′ of FIG. 5.

The semiconductor chip body 114 is attached to a base body 142 of a base substrate 144.

The base body 142 may have, for example, a plate form (although the base body 142 is not limited only to a plate form). Examples of the base body 142 include any one of a synthesized resin substrate, a metal substrate, and a printed circuit substrate. The base substrate 144 also includes an adhesive layer 140 formed on the base body 142.

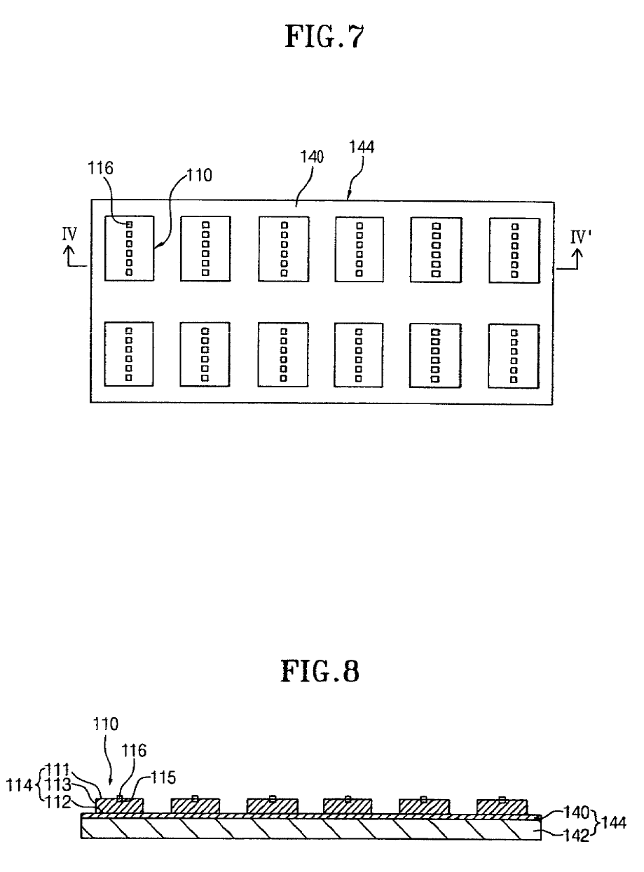

FIG. 7 is a top view shown for illustrating a plurality of the semiconductor chips shown in FIG. 4 being attached to the base substrate shown in FIG. 6. FIG. 8 is a cross-sectional view taken along the line IV-IV′ of FIG. 7.

Referring to FIG. 7 and FIG. 8, an adhesive layer 140 is interposed between the base body 142 and the semiconductor chip body 114 so that the base body 142 and the semiconductor chip body 114 are bonded to each other. Examples of the adhesive layer 140 include a both-surface adhesion tape or anther suitable adhesive.

In the embodiment of the present invention shown in FIG. 7, a plurality of the semiconductor chips 110 are attached to the base substrate 114 in a matrix form. For example, the semiconductor chips 110 are arranged in an m×n matrix where m and n are natural numbers. In the embodiment of the present invention shown in FIG. 7 and FIG. 8, the semiconductor chips 110 are arranged in a 6×2 matrix form on the base substrate 144.

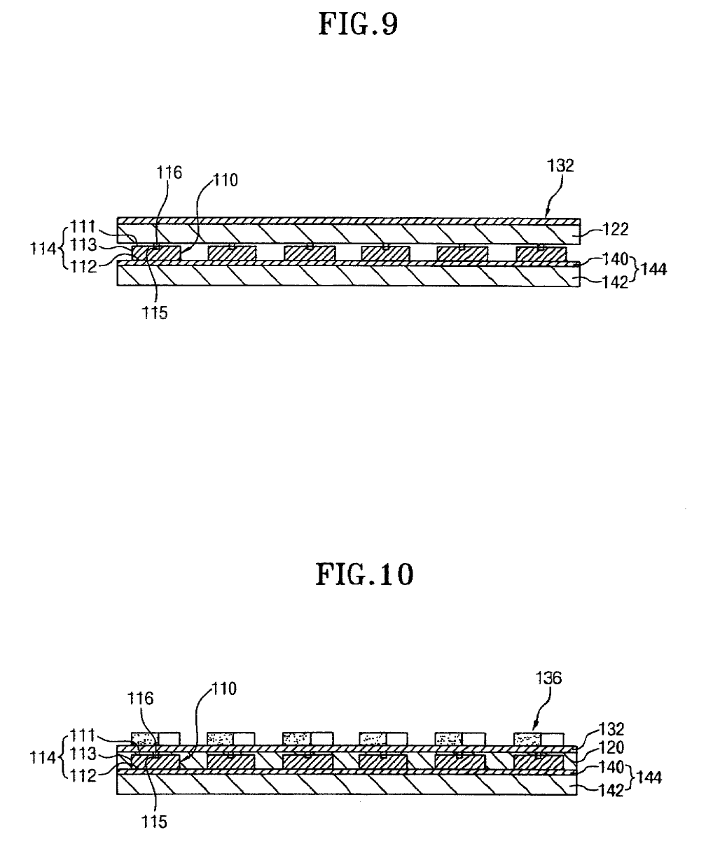

FIG. 9 and FIG. 10 are cross-sectional views shown for illustrating a process of forming a wiring support member on the base substrate shown in FIG. 8.

Referring to FIG. 9, a preliminary wiring support member 122 having, for example, a plate form is disposed on a top portion of the semiconductor chips 110 attached to the adhesive layer 140 of the base substrate 144. The preliminary wiring support member 122 has substantially the same shape and area as the base substrate 144, when viewed on a plane.

The preliminary wiring support member 122 according to one embodiment of the present invention has, for example, a plate shape and the preliminary wiring support member 122 includes a thermo-setting resin having characteristics such that it is hardened by applying heat and then is not softened even when heat is applied again.

Meanwhile, before heat-pressurizing the preliminary wiring support member 122 on the base substrate 144, a metal layer 132 having a thin thickness can be formed on a top surface of the preliminary wiring support member 122. In embodiments of the present invention, copper, copper alloy, aluminum and aluminum alloy are examples of material suitable for use as the metal layer 132.

The metal layer 132 disposed on the preliminary wiring support member 122 can be formed via a sputtering process, a chemical vapor deposition process or electroless plating process. Alternatively, the metal layer 132 having a thin thickness may be disposed on the preliminary wiring support member 122 using a conductive adhesive.

In this embodiment of the present invention, the metal layer 132 is patterned to form the wiring 130 described above, such that since the bump 116 of the semiconductor chip 110 is caused to be exposed from the wiring support member 120 the wirings 130 can be electrically connected to the bumps 116. The wirings 130 are described in more detail later.

Referring to FIG. 10, heat and pressure are applied to the preliminary wiring support member 122 after the preliminary wiring support member 122 is disposed on the semiconductor chip 110. As such, the preliminary wiring support member 122 containing the thermo-setting resin is subjected to a heat-pressure process so that the wiring support member 120 is formed to surround the top surface 111 and the side surfaces 113 of the semiconductor chip 110 while exposing the bumps 116. At this time, the metal layer 132 is electrically connected to each of bumps 116 of the semiconductor chip 110 as the preliminary wiring support member 122 is melted.

Meanwhile, the wiring support member 120 can also be formed to surround the top surface 111 and the side surfaces 113 of the semiconductor chip 110 by melting the preliminary wiring support member 122.

A photo-resist film (not shown) is formed over the entire area of the metal layer 132 so that the wiring 130 can be formed using the metal layer 132 disposed on the wiring support member 120. The photo-resist film can be formed by, for example, a spin coating process, a printing process or a rolling process.

After forming the photo-resist film, the photo-resist film is patterned using a photo process that includes a photo-exposure process and a developing process so that a photo-resist pattern 136 having substantially the same shape as that of the wirings 130 shown in FIG. 1 is formed on the metal layer 132.

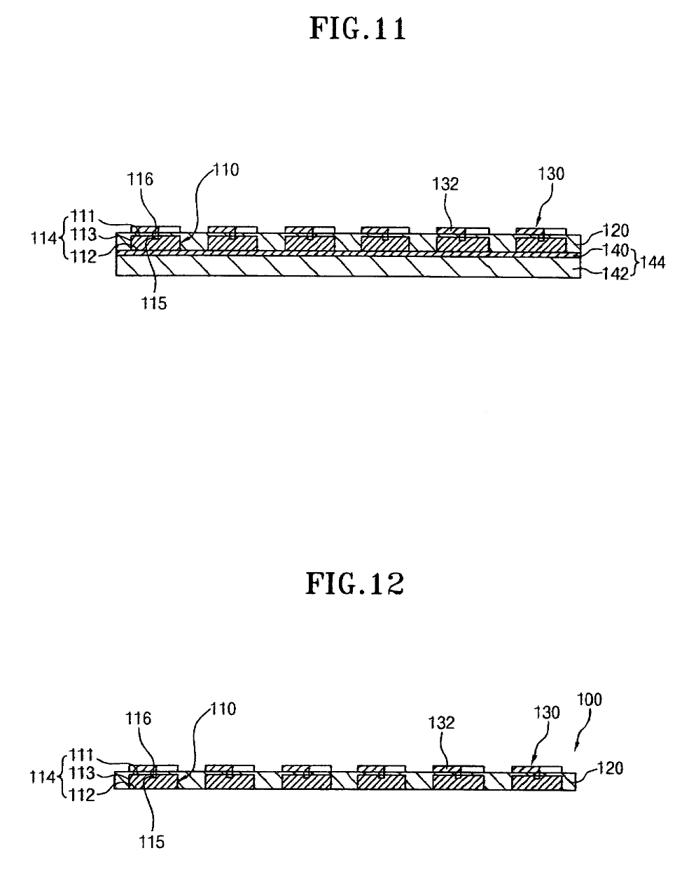

FIG. 11 is a cross-sectional view shown for illustrating that the formation of wirings by patterning the metal layer shown in FIG. 10.

Referring to FIG. 11, the metal layer 132 is patterned using the photo-resist pattern 136 as a pattern mask so that the wirings 130 are formed on the wiring support member 120 (as shown in more detail in FIG. 1). One-side end of the wirings 130 is electrically connected to the bumps 116, and the other-side end opposite to the one-side end of each wiring 130 extends towards the edge of the top surface 111 of each semiconductor chip (i.e., extends to an area corresponding to the edge of the top surface 111 of each semiconductor chip 110).

In the embodiment of the present invention described above, the wirings 130 are formed by patterning the metal layer 132 after forming the metal layer 132 and the photo-resist pattern 136 on the preliminary wiring support member 122. In one alternative embodiment of the present invention, the wiring can be formed by forming the metal layer 132 after the wiring support member 120 has already been formed and then patterning the metal layer to form the wiring 130, such that the metal layer 132 and the photo-resist pattern 136 are formed on the wiring support member 120 rather than the metal layer 132 being formed on the preliminary wiring support member 122.

The wiring 130 according to an embodiment of the present invention can be formed via the plating process using a metal seed layer and a photo-resist pattern.

Meanwhile, one portion of the wiring 130 can formed such that the portion extends beyond the side surface 113 of the semiconductor chip 110 (as shown in FIG. 1 and FIG. 2). If the wiring 130 extends beyond the side surface 113 of the semiconductor chip 110, a connection terminal having a very small size can be disposed on the semiconductor chip 110 in accordance with Joint Electron Devices Engineering Council (JEDEC) provisions.

In the embodiments of the present invention described above, it is possible to both reduce the number of processes required for manufacturing the semiconductor package and reduce considerably the volume of the semiconductor package, by using the wiring support member that includes the thermo-setting material.

Referring to FIG. 12, after the wiring 130 is formed on the wiring support member 120, the base body 142 of the base substrate 144 is separated from the adhesive layer 140. Thereafter, each of the semiconductor chips 110 and the corresponding wiring support member 120 are individualized, thereby producing a plurality of semiconductor packages. Alternatively, after the wiring 130 is formed on the wiring support member 120, the base substrate 144 including the adhesive layer 140 and the base body 142 can be removed from the semiconductor chip 110.

Though the base substrate 144 is removed from the semiconductor chip 110 after the wiring 130 is formed on the wiring support member 120 according to one embodiment of the present invention, alternatively the base substrate 144 can be removed after forming the wiring support member 120 and before forming the wiring 130.

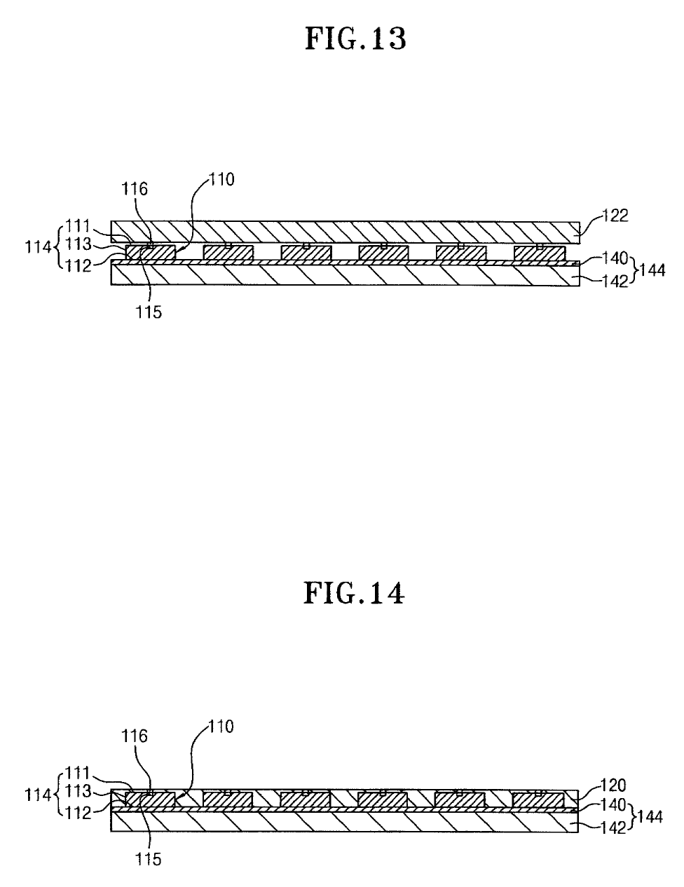

FIGS. 13 to 16 are cross-sectional views shown for illustrating a method for manufacturing a semiconductor package according to another embodiment of the present invention. A detailed description of the steps illustrated in FIGS. 13 to 16 that are substantially similar to those illustrated in FIGS. 3 to 8 will be omitted, and like terms and like reference numerals denote like elements.

Referring to FIG. 13, the preliminary wiring support member 122 (which has, for example, a plate form) is disposed on the top surface of the semiconductor chips 110 attached on the adhesive layer 140 of the base substrate 144. In one embodiment of the present invention, the preliminary wiring support member 122 has substantially the same shape and area as the base substrate 144 when viewing on a plane.

The preliminary wiring support member 122 according to an embodiment of the present invention has, for example, a plate shape, and the preliminary wiring support member 122 contains a thermo-setting resin having characteristics such that it is hardened by applying heat and then is not softened even when heat is applied again.

Referring to FIG. 14, heat and pressure are applied to the preliminary wiring support member 122 after the preliminary wiring support member 122 containing thermo-setting resin is disposed on the semiconductor chip 110. Alternatively, a sufficient amount of heat can be applied to the preliminary wiring support member 122 so that the preliminary wiring support member 122 melts.

As the preliminary wiring support member 122 is heat-pressurized on the base substrate 144, the wiring support member 120 is formed to surround the top surface 111 and side surfaces 113 of the semiconductor chip 110 and is formed on the adhesive layers 140 of the base substrate 144. At this time, the wiring support member 120 covers each bump 116 formed on the top surface of the semiconductor chip 110.

If each bump 116 is covered by the wiring support member 120 after the wiring support member 120 is formed in the embodiment of the present invention, a process of exposing each bump 116 to the outside by polishing or etching the surface of the wiring support member 120 is additionally performed.

Though the wiring support member is formed by heat-pressurizing or melting the preliminary wiring support member 122 of plate shape in this embodiment, the wiring support member can also be formed by applying the preliminary wiring support material of liquid phase to the base substrate 144 and performing a semi-curing process or a curing process.

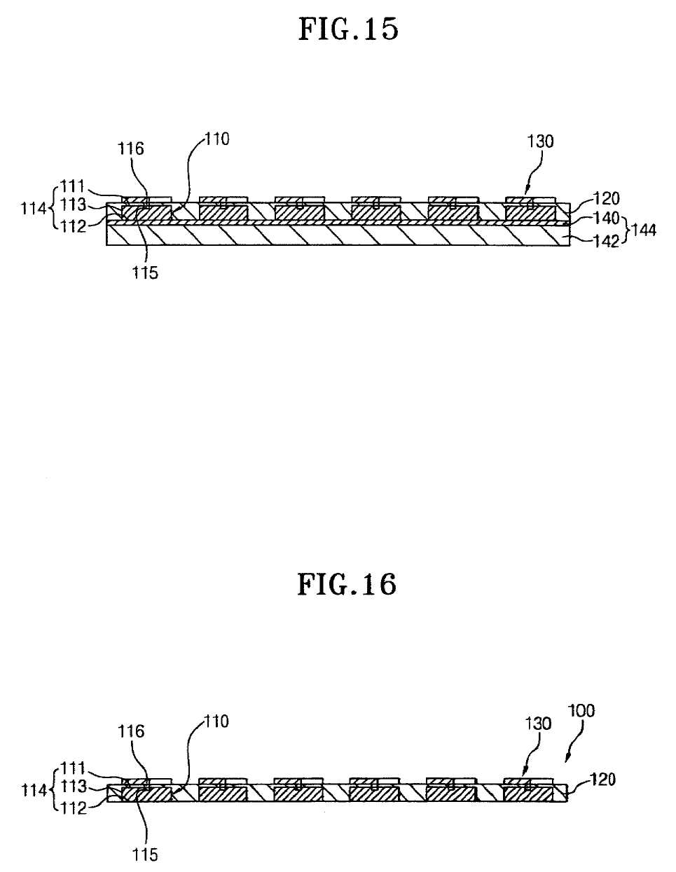

Referring to FIG. 15, the wirings 130, each electrically connected to a respective bump 116, are formed on the wiring support member 120 via a plating process after the wiring support member 120 exposing each bump 116 is formed.

More specifically, a metal seed layer (not shown) is formed on the wiring support member 120 in order to perform the plating process and a photo-resist film (not shown) is formed over the entire area of the metal seed layer (not shown).

Subsequently, the photo-resist film is patterned by a photo process including a photo-exposure process and a developing process, thereby forming the photo-resist pattern (not shown) of which an area where each wiring 130 is to be formed is open as shown in FIG. 1.

Subsequently, the plating process is performed on the metal seed layer exposed by the photo resist pattern using the photo-resist pattern as the plating mask and the wirings 130 are formed on the wiring support member 120.

Subsequently, the photo-resist pattern is removed from the metal seed layer and the metal seed layer formed on the wiring support member 120 is eliminated using the wiring 130 as an etch mask.

FIG. 16 is a cross-sectional view shown for illustrating the removal of the base substrate shown in FIG. 15.

Referring to FIG. 16, after the wiring 130 is formed on the wiring support member 120, the base body 142 of the base substrate 144 is separated from the adhesive layer 140 and each of the semiconductor chips 110 and the corresponding wiring support member 120 are individualized, thereby producing a plurality of semiconductor packages. Alternatively, the base substrate 144 including the adhesive layer 140 and the base body 142 can be removed from the semiconductor chip 110 after the wiring 130 is formed on the wiring support member 120.

Though the base substrate 144 is removed after the wiring 130 is formed on the wiring support member 120 according to one embodiment of the present invention, the base substrate 144 can be alternatively removed after forming the wiring support member 120 and before forming the wiring 130.

After the base substrate 144 is removed from the semiconductor chip 110 and the wiring support member 120, a heat sink plate (see FIG. 2) can be disposed on the bottom surface 112 of the semiconductor chip 110 in order to dissipate heat generated by the semiconductor chip 110.

FIG. 17 is a cross-sectional view shown for illustrating a method for manufacturing the semiconductor package according to another embodiment of the present invention.

Referring to FIG. 17, a semiconductor chip 110 having bumps 116 electrically connected to bonding pads 115 disposed on the top surface 111 of the semiconductor body 114 is prepared in order to manufacture the semiconductor package.

Thereafter, the bottom surface 112 opposite to the top surface 111 of the semiconductor chip 110 is attached on the base substrate 142. At this time, an adhesive layer 144 is interposed between the semiconductor chip 110 and the base substrate 142, so that the semiconductor chip 110 and the base substrate 142 are bonded by the adhesive layer 144.

After the semiconductor chip 110 is attached to the base substrate 142, the base substrate 142 having the semiconductor chip 110 attached thereto is disposed within a mold 220 having an upper mold 210 with an injection hole 212 through which molding materials are injected and a lower mold 220 to support the base substrate 142. The upper mold 210 has a flat surface 214, and the flat surface 214 directly contacts the bumps 116 of the semiconductor 110. Therefore, a space is formed between the top surface of the semiconductor chip 110 and the flat surface 214 of the upper mold 210.

Subsequently, the molding material, such as, for example, an epoxy resin, is provided through the injection hole 212, and thus the space between the upper mold 210 and the lower mold 220 is filled with the molding material so that the wiring support member 120 is formed to expose the bumps 116 of the semiconductor chip 110.

Thereafter, wirings 130 electrically connected to the bumps 116 are formed on the wiring support member 120 as shown in FIG. 15.

In one embodiment of the present invention, the metal layer is formed on the wiring support member 120 in order to form the wirings 130, and a photo-resist pattern is formed on the top surface of the metal layer. The photo-resist pattern has substantially the same size and shape the wiring 130 shown in FIG. 1. Thereafter, the metal layer is patterned using the photo-resist pattern as etch mask so that the respective wirings 130 are formed to be electrically connected to the respective bumps 116. Alternatively, the wiring 130 can be formed by the plating process described above.

As described above, in the present invention, it is possible to both reduce the number of processes required for manufacturing the semiconductor package and reduce the thickness of the semiconductor package.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor package, comprising:
a semiconductor chip having a top surface, a bottom surface opposite to the top surface and side surfaces joining the top and bottom surfaces, the semiconductor chip comprising one or more bonding pads disposed on the upper surface;
one or more bumps each electrically connected to a respective bonding pad;
a wiring support member covering the top surface and the side surfaces of the semiconductor chip, wherein the wiring support member comprises a material that is moldable prior to being hardened allowing the wiring support member to cover the top surface and side surfaces of the semiconductor chip while exposing each of the bumps; and
one or more wirings disposed on the wiring support member and electrically connected to the one or more exposed bumps.

2. The semiconductor package according to claim 1, wherein the wiring support member comprises a thermo-setting resin.

3. The semiconductor package according to claim 1, further comprising an adhesive layer attached on the bottom surface of the semiconductor chip.

4. The semiconductor package according to claim 3, further comprising a heat sink plate disposed on the adhesive layer.

5. The semiconductor package according to claim 1, wherein the wiring support member comprises a molding material and the molding material comprises an epoxy resin.

6. The semiconductor package according to claim 11 wherein each of the one or more bumps protrude from the top surface of the semiconductor chip by a predetermined height and a top surface of the bump and a top surface of the wiring support member are substantially coplanar.

7. A method for manufacturing a semiconductor package, comprising steps of:
providing a semiconductor chip having a top surface, a bottom surface opposite to the top surface and side surfaces joining the top and bottom surfaces, the top surface including bonding pads, and bumps each formed on a respective bonding pad and electrically connected to the respective bonding pad;
attaching the bottom surface of the semiconductor chip to a base substrate;
disposing a preliminary wiring support member on the bumps;
forming a wiring support member over the base substrate by molding the preliminary wiring support member such that the wiring support member covers the top surface and the side surfaces of the semiconductor chip while exposing each of the bumps;
forming wirings on the wiring support member such that the wirings are electrically connected to the bumps; and
removing the base substrate from the semiconductor chip and the wiring support member.

8. The method according to claim 6, wherein the step of attaching the bottom surface on the base substrate further comprises interposing an adhesive member between the base substrate and the semiconductor chip.

9. The method according to claim 6, wherein the step of forming the wiring support member on the base substrate comprises steps of:
disposing the preliminary wiring support member on the top surface of the semiconductor chip, wherein the disposed preliminary wiring support member comprises a thermo-setting material; and
performing a heat pressure process on the preliminary wiring support member to form the wiring support member such that the wiring support member covers the top surface and the side surfaces of the semiconductor chip while exposing the bumps from the wiring support member.

10. The method according to claim 7, wherein the step of forming the wirings on the wiring support member comprises forming a metal layer on the wiring support member.

11. The method according to claim 10, wherein the step of forming the wirings further comprises the steps of:
forming a photo-resist pattern on the top surface of the metal layer; and
etching the metal layer using the photo-resist pattern as a pattern mask.

12. The method according to claim 7, wherein the step of forming the wirings comprises steps of:
forming a metal layer on the wiring support member such that the metal layer is electrically connected to each of the bumps;
forming a photo-resist pattern on the top surface of the metal layer; and
etching the metal layer using the photo-resist pattern as a pattern mask.

13. The method according to claim 7, wherein the wirings are formed via a plating process.

14. The method according to claim 7, wherein the step of forming the wiring support member on the base substrate comprises steps of:
disposing the preliminary wiring support member on the top surface of the semiconductor chip, wherein the preliminary wiring support member comprises a thermo-setting material; and
covering the top surface and the side surfaces of the semiconductor chip while exposing the bumps from the preliminary wiring support member by melting the preliminary wiring support member.

15. The method according to claim 6, wherein the step of forming the wiring support member on the base substrate comprises:
forming the wiring support member on the base substrate such that the wiring support member covers the top surface and the side surfaces of the semiconductor chip including the bumps; and
exposing each bump by polishing or etching the surface of the wiring support member.

16. The method according to claim 6, wherein the preliminary wiring support member has a liquid phase, and the wiring support member is formed by semi-curing or curing the preliminary wiring support member.

17. A method for manufacturing a semiconductor package, comprising steps of:
providing a semiconductor chip having a top surface, a bottom surface opposite to the top surface, and side surfaces joining the top and bottom surfaces, the top surface including bonding pads, and bumps each formed on a respective bonding pad and electrically connected to the respective bonding pad;
attaching the bottom surface of the semiconductor chip to a base substrate;
disposing the base substrate with the attached semiconductor chip being attached thereon within a mold;
forming a molding member having a molding material injected into the mold to cover the top surface and the side surfaces of the semiconductor chip while exposing the bonding pads;
forming wirings on the molding member such that the wirings are electrically connected to the bumps; and
removing the base substrate from the semiconductor chip and the wiring support member.

18. The method according to claim 17, wherein the step of attaching the bottom surface on the base substrate further comprises interposing an adhesive member between the base substrate and the semiconductor chip.

19. The method according to claim 17, further comprising steps of:
after forming the wiring support member,
forming a metal layer on the wiring support member;
forming a photo-resist pattern on a top surface of the metal layer; and
etching the metal layer using the photo-resist pattern as a pattern mask.

20. The method according to claim 17, wherein the wirings are formed by a plating process.
